(19) United States
(12) Patent Application Publication
(10) Pub. No.: US 2005/0156176 A1
(43) Pub. Date: Jul. 21, 2005

(54) Method for printing organic devices

(76) Inventors: Rahul Gupta, Milpitas, CA (US); Andrew Ingle, Fremont, CA (US)

Correspondence Address: Siemens Corporation;Attn: Elsa Keller, Legal Administrator, Intellectual Property Administrator, 170 Wood Avenue South, Iselin, NJ, 08830, US

(21) Appl. No.: 10/812,567

(22) Filed: Mar. 30, 2004

Related U.S. Application Data
(60) Provisional application No. 60/537,414, filed on Jan. 16, 2004.

(51) Int. Cl. H01L 29/26; H01L 27/15; H01L 31/12

(52) U.S. Cl. 257/79; 257/40; 257/81

(57) ABSTRACT

In accordance with the invention, a method for fabricating an organic electronic device is disclosed. The method consists primarily of 1) depositing a first organic solution by inkjet or other techniques, 2) cross-linking the deposited and dried (or partially dry or not dried organic film resulting therefrom, and then 3) depositing a second organic solution over the cross-linked film.

### CROSS-REFERENCE TO RELATED APPLICATIONS

This application claims priority from a provisional patent application entitled “Method for Printing Organic Devices” filed on Jan. 16, 2004 bearing Ser. No. 60/537,414.

### BACKGROUND

1. Field of the Invention

This invention relates generally to the art of thin film device processing and fabrication. More specifically, the invention relates to the fabrication of Organic Light Emitting Diode based displays and other devices.

2. Related Art

Display and lighting systems based on LEDs (Light Emitting Diodes) have a variety of applications. Such display and lighting systems are designed by arranging a plurality of photo-electronic elements (“elements”) such as arrays of individual LEDs. LEDs that are based upon semiconductor technology have traditionally used inorganic materials, but recently, the organic LED (“OLED”) has come into vogue for certain applications. Examples of other elements/devices using organic materials include organic solar cells, organic transistors, organic detectors, and organic lasers. There are also a number of bio-technology applications such as biochips for DNA recognition, combinatorial synthesis, etc. which utilize organic materials.

An OLED is typically comprised of two or more thin at least partially conducting organic layers (e.g., an electrically conducting hole transporting polymer layer (HTLs) and an emissive polymer layer where the emissive polymer layer emits light) which are sandwiched between an anode and a cathode. Under an applied forward potential, the anode injects holes into the conducting polymer layer, while the cathode injects electrons into the emissive polymer layer. The injected holes and electrons each migrate toward the oppositely charged electrode and recombine to form an exciton in the emissive polymer layer. The exciton relaxes to a lower energy state by emission of radiation and in process, emits light.

Other organic devices, such as organic transistors, organic sensors, color filters and phosphors will also typically contain a conducting organic (polymer) layer and other organic layers. A number of these OLEDs or other organic devices can be arranged in a pattern over a substrate as for instance in display system. One way of patterning organic electronic devices over a substrate is to create pockets by photo-lithography and then utilize a process known as ink-jet printing. The use of a photo-resist layer to define pockets for inkjet printing is disclosed in published patent application Number U.S. 2002/0060518 A1 entitled “Organic Electroluminescent Device and Method of Manufacturing Thereof”. In ink-jet printing, polymer or organic solution is deposited by discharging droplets of the solution into the pockets from a print head. One common application of inkjet printing is the patterning of multi-color OLED pixels (such as RGB patterned pixels) in order to manufacture a color display.

But inkjet printing and other selective deposition techniques which fabricate polymer films for devices have some limitations. One limitation is in being able to achieve multi-layer or “hetero-structure” devices that have adjacent films that are soluble in the same type of solvents. This is because each polymer solution which is deposited remains soluble even after drying. When an additional organic layer is required to be fabricated over an existing layer, the existing layer can only be made of a material which will not be soluble under the same solvent being used to deposit the additional layer. Otherwise, existing layers will be degraded substantially or even dissolved.

Recent developments have shown that UV curable inks can be used to deposit dye pigments for printing posters and textiles (U.S. Patent Application No. 20020044188). UV curable inks are solutions which cure or dry into film under application of ultraviolet or other radiation. For spin-coating (rather than selective deposition such as inkjet printing) techniques, a recent publication has outlined the use of “cross-linked” polymers to make RGB displays. See “Multi-colour organic light-emitting displays by solution processing”; C. David Müller, Aurelie Falcou, Nina Reckefuss, Markus Rojahn, Valérie Wiederhirn, Paula Rudati, Holger Frohne, Oskar Nuyken, Heinrich Becker, Klaus Meerholz; Nature Volume 421, Pages 829-833 (20 Feb. 2003). A cross-linked (or “cross-linkable”) polymer is a polymer which has been modified by the addition of a chemical group which chemically reacts with the original polymer to create side-chains which can alter the polymer's properties. In this publication, the authors propose spin coating UV curable inks that are then cross-linked such that the resulting film becomes insoluble. The films are then patterned to create the colored displays. This suffers from the drawback that additional processing is required on the deposited films in order to pattern them.

Thus there is a need for techniques which can efficiently create patterned devices that have hetero-structures wherein additional layers may be added to existing layers without degrading the integrity of existing layers.

### SUMMARY

In accordance with the invention, a method for fabricating an organic electronic device is disclosed. The method consists primarily of 1) depositing a first organic solution by inkjet or other techniques, 2) cross-linking the deposited and dried (or partially dry or not dried organic film resulting therefrom, and then 3) depositing a second organic solution over the cross-linked film.

### BRIEF DESCRIPTION OF THE DRAWINGS

FIG. 1 illustrates a method of fabricating an organic electronic device according to at least one embodiment of the invention.

FIG. 2 illustrates stages of inkjet processing of a organic multi-layer device in accordance with at least one embodiment of the invention.

FIG. 3 illustrates a process to fabricate a patterned three-color OLED device according to one or more embodiments of the invention.

FIG. 4 shows a cross-sectional view of an embodiment of an organic electronic device 405 according to the invention.

### DETAILED DESCRIPTION OF THE INVENTION

In accordance with the invention, a method for fabricating an organic electronic device is disclosed. The method consists primarily of 1) depositing a first organic solution by inkjet or other techniques, 2) cross-linking the deposited and dried (or partially dry or not dried organic film resulting therefrom), and then 3) depositing a second organic solution over the cross-linked film. This process can be extended to create hetero-structure devices containing three or more layers of film as well. Cross-linking is desirable if a previously deposited layer/film is soluble in the organic solution that is to follow. In such a case, cross-linking of the previously formed organic layer will cause it to become insoluble and thus, will prevent that layer from being degraded by another organic solution that is deposited over it.

In one embodiment of the invention, the organic solution used in fabricating the organic electronic device includes UV (ultra-violet) curable inks. UV curable inks are capable of being cross-linked by exposure to ultraviolet radiation. In other embodiments of the invention, the organic solutions used and thermally curable and thus, can be cross-linked by exposure to heat.

In other embodiments of the invention, a patterned organic electronic device such as a multi-color OLED display can be created by 1) depositing and cross-linking solution of one color, and then 2) depositing solution of a second color, 3) masking regions of the display where the first color is present, and then 3) cross-linking solution of a second color. An alternate way would be to use a scanning beam to crosslink the polymer selectively in the required regions of the sample. This process can be extended for two or more colors such as a three-color RGB OLED display. In some embodiments of the invention, a cross-linkable group can be grafted onto the active polymer, and then the newly synthesized polymer solution is then deposited and cross-linked. In other embodiments of the invention, the active polymer species (such as an emissive polymer) can be added to a cross-linking polymer matrix.

In accordance with the invention, the optical spectrum and dosage of ultra-violet radiation or heat, i.e. the “curing level,” which is defined in part by the intensity and exposure time, can be varied as needed to control the thickness of the resulting film. In general, the higher the curing level, the greater the thickness of the cross-linked organic film. In some embodiments of the invention, the exposure of the solution for the purpose of cross-linking is performed from the bottom of the device, which can lead to a flatter resulting film and allow the excess solution to be removed from the top by washing or other means. Bottom exposure also enables very good thickness control as the absorption depth of the liquid deposited determines the thickness of the film that is cross-linked.

The combination of inkjet printing with crosslinking of films yields some advantages in flexibility of design. For example, for a multi-color display application, it may be possible to achieve different thickness for the different layers used for each color. This would allow the use of a greater number of different materials for each color than is currently available due to concerns of dissolving pre-existing layers. The same technique can be used to fabricate color filters, phosphors or any other materials for varied applications.

In describing the invention, the terms “solution” “layer” and “film” refer to the same entity which may be under different physical states. When an organic “solution” is deposited on a surface, it often dries over time into a “film” often aided by heat or other mechanism. The film then becomes a layer of the device capable of carrying out specific functions. Also, the words “polymer solution” and “organic solution” are used interchangeably to refer to any organic compound, monomer, polymer, copolymer, blends of any of the aforementioned materials and the like and is not intended to be restrictive to any one organic compound or class of compounds.

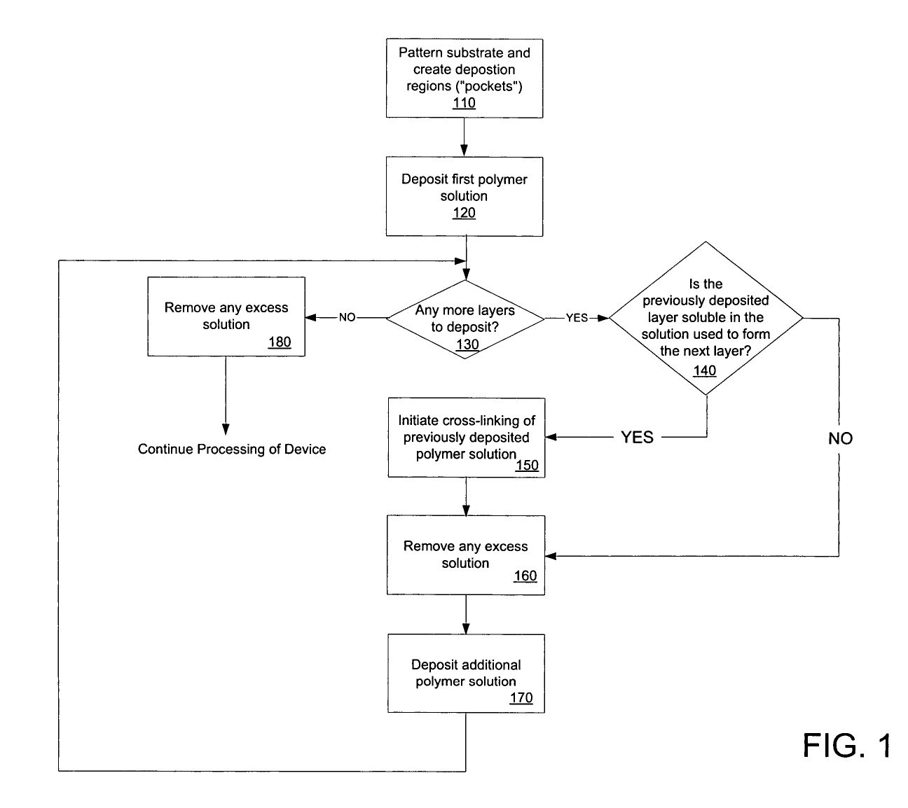

FIG. 1 illustrates a method of fabricating an organic electronic device according to at least one embodiment of the invention. A substrate is patterned in order to create deposition regions or pockets (block 110). The patterning of the substrate also presupposes steps such as the adding and patterning of a lower electrode or anode layer in the case of an OLED. In addition, it may include any other layers or steps needed to create the deposition surface over which an organic film is to be formed. In the case of inkjet printing, therefore, block 110 may also involve adding, for instance, a photo-resist layer which can be patterned to create the needed pockets which surround the deposition surface. The pockets may also be defined using other patterned layers made from materials such as glass etc.

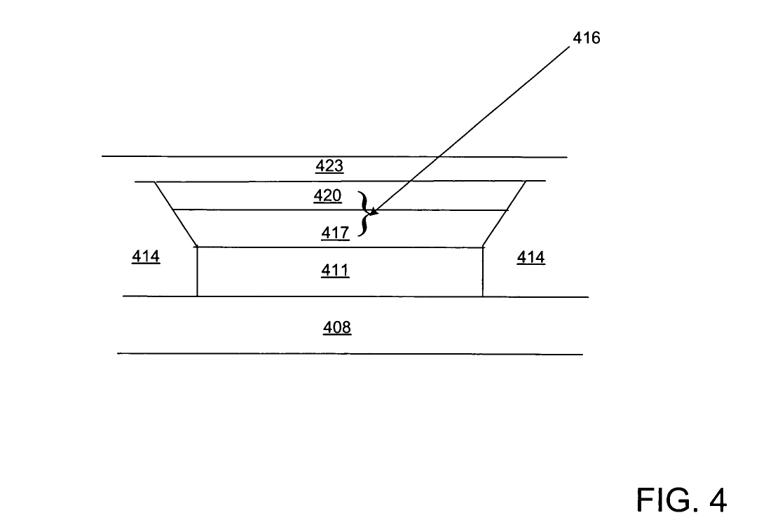

Then a first organic solution is deposited on the deposition surface (block 120). The first organic solution in the case of a bottom-emitting OLED (see FIG. 4 and associated description) the first organic solution might be used to create a hole transport layer (HTL). The solution, once deposited, will begin to dry into a film with a certain profile. If there are more layers to deposit (checked at block 130) as is the case in a multi-layer device, then cross-linking would be needed if the previously deposited layer is soluble in the solvent used in the solution forming the next layer (checked at block 140).

If this is the case, then cross-linking of the previously deposited solution (film) is initiated (block 150). If not, any excess solution is removed by washing, for example (block 160) without cross-linking. Cross-linking of the deposited solution (film) will cause the film to become insoluble. Cross-linking initiation may involve the addition of an initiator compound either after or prior to deposition. In some embodiments of the invention, the cross-linking side-groups included in the polymer chains and/or initiator compounds may already have been blended with the polymer solution prior to deposition (e.g. at block 120). Cross-linking is commenced by applying either ultra-violet radiation or heat, depending upon the properties of the deposited solution. In a preferred embodiment of the invention, the deposited solution is UV-curable and hence, can be cross-linked by the application of ultra-violet radiation. The chemistry and physics of cross-linking polymers and monomers with side groups and chains is well-known in the art and is not discussed in great detail.

In one embodiment of the invention, the ultra-violet or other radiation is provided in a directed manner from the bottom side of the device through a partially transparent substrate (opposite from the direction of deposition and the side of the device from which the solution is deposited). The depth of cross-linking into the film can be controlled in such instances. If there is any excess solution remaining which has not been cross-linked, this can be removed (block 160) to prevent contamination with later-deposited solutions.

Once the previously deposited solution is cross-linked (block 150) and the excess (non-cross-linked) solution is removed, then the next organic solution is deposited (block 170). In the case of bottom-emitting OLED, the second organic layer may be the emissive polymer layer, and hence this solution could be an emissive polymer solution. The solution deposited according to block 170 can use a solvent which would ordinarily dissolve the previously deposited layer since the previously deposited layer has been cross-linked to render it insoluble (block 150). Without any further curing or cross-linking, the next polymer solution will dry into a film above the previously deposited cross-linked film. If there are no more layers to deposit, then any excess solution, if necessary, is removed from the dried film and device processing continues (block 180).

If on the other hand, there are still more layers to deposit (initially, more than two) (block 130), then process flow returns to block 140. If the previously deposited layer is soluble in the solution used to form the next (to-be-deposited) layer, then cross-linking is initiated (block 150) and process flow continues. If not, excess solution is removed (block 160) without cross-linking and the next layer is deposited (block 170). If there are no more layers to deposit (checked at block 130), then excess solution, if any, is removed (block 180). The process shown is repeated until there are no more organic layers to deposit. Other device processing steps (such as adding cathode metal in the case of an OLED) then commence. A specific application of this technique is described below with respect to FIG. 4. By cross-linking each preceding layer, any number of layers may be deposited upon one another, with little regard to solubility issues. This adds to design flexibility by allowing a wider range of organic materials to be used in conjunction with one another. For instance, a three or four organic layer device can be fabricated efficiently with deposition techniques such as inkjet printing even though each layer may be soluble in the same or similar solvents.

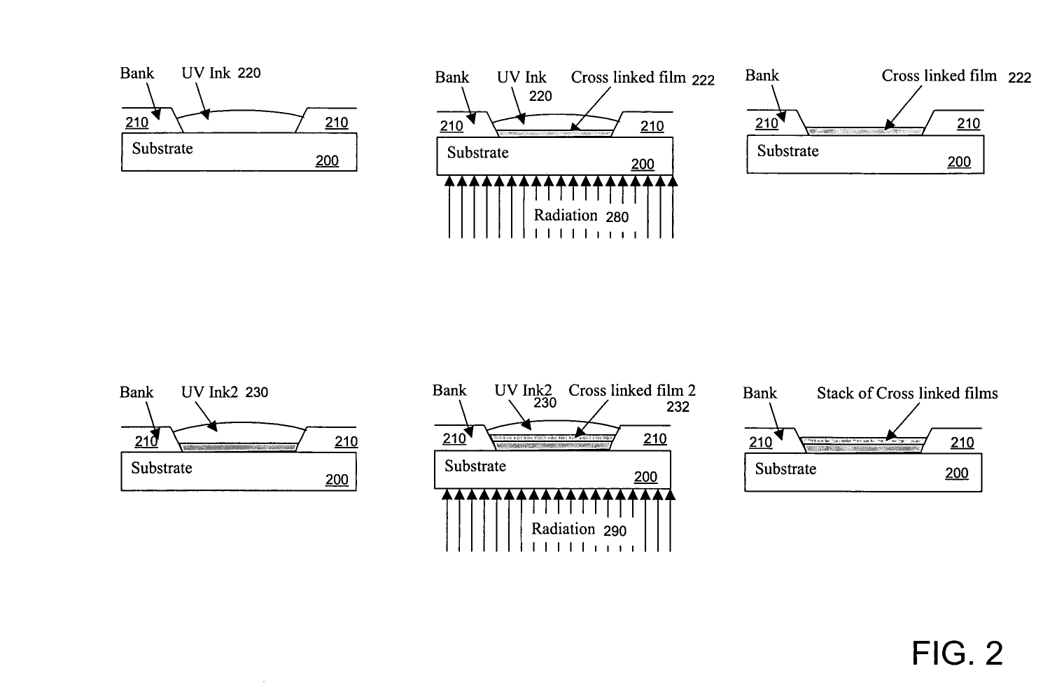

FIG. 2 illustrates stages of inkjet processing of an organic multi-layer device in accordance with at least one embodiment of the invention. The organic electronic device illustrated in FIG. 2 includes a substrate 200 which may have other materials (like an anode in the case of an OLED) patterned on its surface (not shown). Substrate 200 may be any appropriate deposition surface which will vary in composition, structure and material depending upon the type of device to be fabricated. In order to form pockets or discrete deposition regions on the surface of the substrate 200, photo-resist banks 210 are formed and patterned over the substrate 200. This allows a substance such as a UV-curable ink 220 to be deposited into the pocket defined by the banks 210 and onto the surface of the substrate 200 (stage A). Inkjet printing may also be performed without the use of photo-resist banks. Furthermore, photo-resist banks, if used, may be made of many materials and can be formed by etching the bank pattern into the lower electrode or substrate. The UV ink 220 is inkjet or otherwise is deposited onto substrate 200 to form a convex/dome shape or other shapes if surface treatments or different formulations of solution are used.

At stage B, radiation 280 is applied from the bottom side of the device through the substrate 200 to the UV ink 220. This radiation 280 cures at least a portion of the UV ink 220 (from bottom to top) into a cross-linked film 222. The level of curing which is a function of the optical spectrum of the radiation 280, the intensity of the radiation 280 and time of exposure to radiation 280 will determine and can be used to control the height of the film 222. The cross-linked film 222 is insoluble unlike non-cross-linked film resulting from drying of the same solution 220. If there is excess solution 222 on top of the cross-linked film 222, this can be washed away as shown in stage C.

In stage D, the next organic solution, UV ink2 230 is deposited (e.g. by inkjet) over cross-linked film 222. Then, as shown, a second dose of radiation 290 is applied from the bottom side of the substrate 200 in order to form a cross-linked film 232 from UV ink2 230 (stage E). Radiation 290 may be of the same or different level and/or wavelength as radiation 280, depending upon the content of UV ink2 230. For instance, UV ink2 230 may require a stronger dosage of radiation in order to cure it when compared to UV ink 220. Also, it may be desirable to make the height of the cross-linked 232 different from the height of cross-linked film 222. The level of curing can thus be different for producing film 232 and for producing film 222. Finally, if there is any excess solution 230 that is not cross-linked, it can be removed to leave a flat cross-linked film 232. The cross-linking and stacking of films can be repeated as desired to create hetero-structure devices. At stages B and E radiation may be applied from the top of the device (from above the device) rather than from the bottom, if desirable.

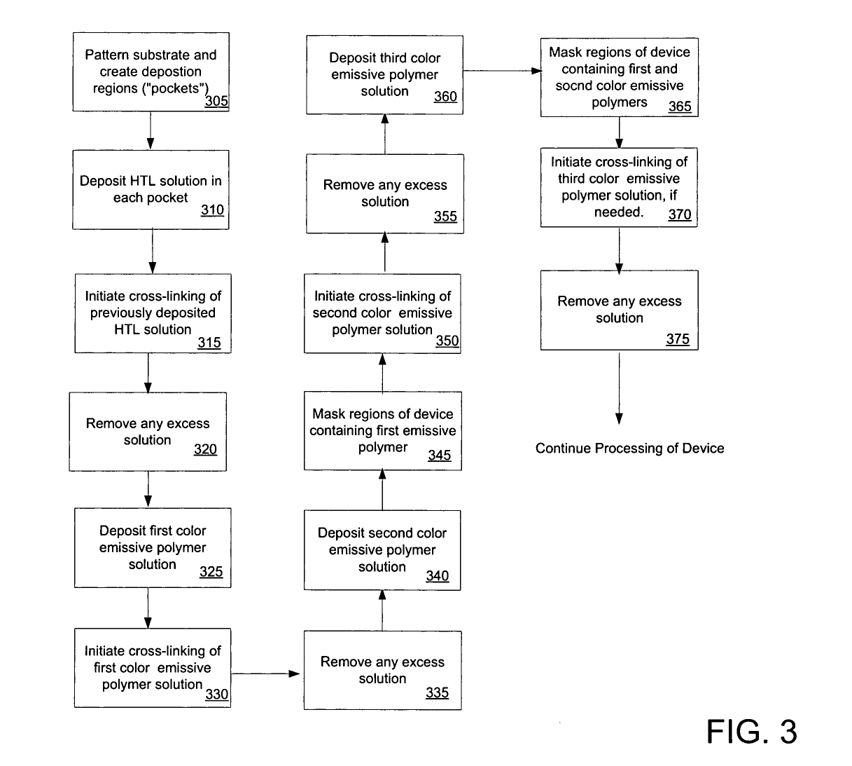

FIG. 3 illustrates a process to fabricate a patterned three-color OLED device according to one or more embodiments of the invention. A three-color OLED display such as an RGB display would include red, green and blue emissive pixels. Each pixel would occupy, in one embodiment, a given pocket (deposition region) which is created over the substrate (and patterned anode) by the use of photo-resist banks as shown in FIG. 2. Selective deposition techniques such as inkjet printing can be used in creating the pattern of pixels of each color. In accordance with the invention, each pocket can also have emissive as well as transport layers cross-linked. Doing so however, involves selective masking to prevent degradation of already cross-linked films due to excessive exposure to ultra-violet radiation. Masking may be implemented from above the substrate if the path of light or radiation is from above the device or from below if the path is from below the device such that the mask selectively blocks or delimits the radiation applied to the device. The masking may contact the device or be placed at some distance, and may be used with a collimated the beam of radiation. The masking can be used with different spread, angle and shape of the radiation beam being applied, if desired. Furthermore, pattered curing can be done through precise positioning of a focused UV beam using a method similar to direct laser writing.

A substrate is patterned in order to create deposition regions or pockets (block 305) which defines pixels (or sub-pixels, depending upon how they are used). The patterning of the substrate steps also presupposes steps such as the adding and patterning of a lower electrode or anode layer of OED display (and thus, of each pixel). In addition, it may include any other layers or steps needed to create the deposition surface over which an organic films are to be fabricated. In the case of inkjet printing, therefore, block 305 would also involve adding, for instance, a photo-resist layer which can be patterned to create the needed pockets which surround the deposition surface.

HTL (Hole Transport Layer) solution is first deposited in each pocket (block 310) (see description associated with FIG. 4 for a more detailed explanation). HTL solution may include, for instance PEDOT:PSS solution and the like. The HTL solution may be inkjet or even spin-coated. According to block 315, cross-linking of the deposited HTL solution is initiated. This step of cross-linking the HTL solution in accordance with block 315 is particularly desirable if the HTL is soluble in the next deposited material. This can be achieved again by applying radiation of appropriate dosage and wavelength to the bottom of the substrate. Again the level of curing can be adjusted to achieve a particular desired height of film. Any excess HTL solution can then be removed (block 320) leaving an insoluble cross-linked HTL layer.

Then the first emissive color polymer solution is deposited (block 325) over the HTL layer. The first color emissive polymer solution can be inkjet into the appropriate pockets (pixels) consistent with creating the pattern for the first color over the device. Thus, only selected pockets of all those available on the display would have emissive polymer solution for the first color deposited. For example, this solution could be used to fabricate a red color emissive polymer layer. Next, the cross-linking of the first color emissive polymer solution is initiated (block 330). Any excess solution is also removed (block 335). Next the second color emissive polymer solution is deposited (block 340). This can be achieved again by ink-jetting the second color emissive polymer solution into those pockets which will continue the desired display pixel pattern. Then, the regions (pockets/pixels) of the display containing the first color emissive polymer film may be masked or shielded to prevent direct exposure to further radiation (block 345). With the masking in place, cross-linking of the second color emissive polymer solution is initiated (block 350). Because of the masking, radiation is selectively applied only to those pockets containing the second color emissive polymer solution. Further, the dosage and wavelength of radiation can be optimized to suit the properties of the second color emissive polymer material, including desired film height. Excess solution, if any, is removed leaving behind a cross-linked second color emissive polymer film (block 355).

Finally, in the three-color case presented, the third color emissive polymer solution is deposited (block 360) by ink-jet preferably. In order to avoid exposure to radiation of the first and second color emissive polymer films, regions of the device containing either the first color emissive polymer or the second color emissive polymer may be masked simultaneously (block 365). Since a mask for regions of the first color emissive polymer has already been utilized, one way of achieving this is to add an additional mask covering the pockets containing the second color emissive polymer and use both first color and second masks in combination. With this dual-color masking in place, cross-linking of the third color polymer solution is initiated (block 370). Finally, any excess solution is removed (block 375) leaving behind a cross-linked third color emissive polymer film.

The process described allows each color emissive polymer to be independently cross-linked and thus, individually tailored to the properties of each color's solution. Further, with the use of ink-jet printing, it would be possible to use a HTL material for each pixel that is optimal for its color. In such cases, each HTL solution could also be independently cross-linked if desired or needed, particularly in the case where the thickness of the resulting HTL film has a height optimized for the emissive color solution that it is intended to support. Though FIG. 3 illustrates a three-color OLED device, the same process can be used to inkjet patterned organic films/devices such as filters and phosphors.

FIG. 4 shows a cross-sectional view of an embodiment of an organic electronic device 405 according to the invention. As shown in FIG. 4, the organic electronic device 405 includes a first electrode 411 on a substrate 408. As used within the specification and the claims, the term “on” includes when layers are in physical contact and when layers are separated by one or more intervening layers. The first electrode 411 may be patterned for pixilated applications or unpatterned for backlight applications. If the electronic device 405 is a transistor, then the first electrode may be, for example, the source and drain contacts of that transistor. A photo-resist material is deposited on the first electrode 411 and patterned to form a bank structure 414 having an aperture that exposes the first electrode 411. The aperture may be a pocket (e.g., a pixel of an OLED display) or a line. The bank structure 414 is an insulating structure that electrically isolates one pocket from another pocket or one line from another line.

One or more organic materials is deposited (preferably ink-jet) into the aperture to form one or more organic layers of an organic stack 416. One or more of the layers (films) comprising organic stack 416 are, in accordance with the invention, cross-linked to become insoluble. The organic stack 416 is on the first electrode 411. The organic stack 416 includes a hole transporting (conducting polymer) layer (“HTL”) 417 and other active organic layer 420. If the first electrode 411 is an anode, then the HTL 417 is on the first electrode 411. Alternatively, if the first electrode 411 is a cathode, then the active electronic layer 420 is on the first electrode 411, and the HTL 417 is on the active electronic layer 420. The electronic device 405 also includes a second electrode 423 on the organic stack 416. If the electronic device 405 is a transistor, then the second electrode 423 may be, for example, the gate contact of that transistor.

Other layers than that shown in FIG. 4 may also be added including insulating layers, electron transport layers, electron blocking layers and the like between the first electrode 411 and the organic stack 416, and/or between the organic stack 416 and the second electrode 423 and/or between active electronic layer 420 and HTL 417). As mentioned these layers can be cross-linked to improve stability or to allow for similarly soluble solutions to be deposited over them to form additional layers. These layers may be selectively deposited only in certain pixels, to optimize the performance of materials being used, for example the electron blocking layer may be needed only for the green emitting pixels. Some of these layers, in accordance with the invention, are described in greater detail below.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of the device.

In accordance with the invention, radiation used to cross-link organic films can be applied from the bottom of the device and through substrate 408 in the case of non-opaque material used for substrate 408. Alternatively, the cross-linking radiation can be applied from the top of the device, particularly with respect to opaque substrates. Thus, it is preferable that the substrate 408 be of a material and with a thickness that enables ultraviolet or other radiation to pass through as needed to achieve cross-linking.

First Electrode 411:

In one configuration, the first electrode 411 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO, and the like); graphite; doped inorganic semiconductors (such as silicon, germanium, gallium arsenide, and the like); and doped conducting polymers (such as polyaniline, polypyrrole, polythiophene, and the like).

For OLEDs, the first electrode layer 411 is usually thin enough so as to be semi-transparent and allow at least a fraction of light to transmit through (in bottom emitting OLEDs). The thickness of the first electrode 411 is from about 10 nm to about 1000 nm, preferably, from about 50 nm to about 200 nm, and more preferably, is about 100 nm. As such, any thin-film deposition method may be used in the fabricating step 510. These include, but are not limited to, vacuum evaporation, sputtering, electron beam deposition, chemical vapor deposition, etching and other techniques known in the art and combinations thereof. The process also usually involves a baking or annealing step in a controlled atmosphere to optimize the conductivity and optical transmission of anode layer. Photolithography can then be used to define any pattern in the lower electrode layer.

In accordance with the invention, the top exposed surface of first electrode 411 might become the deposition surface upon which the organic solution is deposited and cross-linked. In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”.

Bank Structure 414:

The bank structure 414 is made of a photo-resist material such as, for example, polyimides or polysiloxanes. The photo-resist material can be either positive photo-resist material or negative photo-resist material. The bank structure 414 is an insulating structure that electrically isolates one pocket from another pocket or one line from another line. The bank structure 414 has an aperture that exposes the first electrode 411. The aperture may represent a pocket or a line. The bank structure 414 is patterned by applying lithography techniques to the photo-resist material, or by using screen printing or flexo-printing to deposit the bank material in the desired pattern. As shown in FIG. 4, the bank structure 414 can have, for example, a trapezoidal configuration in which the angle between the side wall of the bank structure 414 and the first electrode 411 is an obtuse angle. The banks may also be any other suitable shape such as curved or semi-circular.

Photo-resist material is usually classified in two types, either positive or negative. Positive photo-resist is photo-resist which dissolves wherever exposed to light. Negative photo-resist is photo-resist which dissolves everywhere except where exposed to light. Using light radiation and techniques such as chemical developing, the photo-resist can be patterned into the desired bank shape. Examples of positive resists are those materials comprised of polyimides and so on. Either positive or negative photo-resist can be used as desired in forming the banks. Photo-resist chemistry and processes such as lithography, baking, developing, etching and radiation exposure which can be used in patterning the photo-resist into banks are known to those skilled in the art.

HTL 417:

The HTL 417 has a high hole mobility and is used to effectively transport holes from the first electrode 411 to the substantially uniform organic polymer layer 420. The HTL 417 functions as: (1) a buffer to provide a good bond to the substrate; and/or (2) a hole injection layer to promote hole injection; and/or (3) a hole transport layer to promote hole transport.

The HTL 417 can be formed by deposition of a organic solution, polymers or small molecule materials. For example, the HTL 417 can be made of tertiary amine or carbazole derivatives both in their small molecule or their polymer form, or organic solutions such as conducting polyaniline (“PANI”), or preferably, solutions of “PEDOT:PSS.” A PEDOT:PSS solution is comprised of water, polyethylenedioxythiophene (“PEDOT”), and polystyrenesulfonic acid (“PSS”) (this solution is referred to, herein, as a PEDOT:PSS solution and may be combined with or contain other components as well). The HTL 417 has a thickness from about 5 nm to about 1000 nm, preferably from about 20 nm to about 500 nm, and more preferably from about 50 to about 250 nm. In addition, the solution may be blended with cross-linking side groups or chains which will bind to the base solution (such as the PEDOT:PSS) to render it insoluble.

The HTL 417 can be deposited using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. The hole transporting material is deposited on the first electrode 411 and then dried into a film. The dried material represents the hole transport layer.

As mentioned above, in accordance with the invention, the HTL 417 is cross-linked to render it insoluble. Examples of typical base PEDOT:PSS solution are Baytron P CH8000 and Baytron AI4083. Some embodiments of the invention, combine base PEDOT:PSS solution with another side-group such as multivalent cations or divalent metal ions or amines or other acidic groups which bond to the PEDOT:PSS after cross-linking. For instance, in the case of UV cross-linking. In other embodiments, silanes such as silicic acid can be used as cross-linking agents. In still other embodiments of the invention, it may be possible to cross-link the organic solution used in forming the HTL layer with the substrate or first electrode layer. The chemistry of cross-linking is not a subject of the invention, and the above are provided as merely examples of cross-linking. The side-groups, monomers, oligomers, co-polymers, acids, and so on used in cross-linking will vary based upon the properties of the base HTL solution and upon the method of cross-linking (whether thermal, ultra-violet or chemical). In the case of ultraviolet cross-linking, an initiating agent may also be combined with the base organic solution and cross-linking group to speed up and initiate the cross-linking process. A photo-initiator in such cases can be incorporated into the polymer chain as well, if desirable. One example of cross-linking initiator or agent is a magnesium cation (Mg2) for UV cross-linking. In the case of thermal cross-linking, an organic diamine or other amine/amide can be used to cross-link together the functional HTL sulfonic acids (such as PSS). Certain co-polymer and other side-groups cross-link without the need for an additional initiating agent. The invention can serve to provide an insoluble HTL film which can be ink-jet and allow other organic layers to be ink-jet upon it without undue threat of degrading the existing HTL film.

In some embodiments of the invention, a cross-linkable group can be grafted onto the active hole transporting polymer, and then the newly synthesized polymer solution is then deposited and cross-linked. In other embodiments of the invention, the active polymer species (the hole transporting polymer) can be added to a cross-linking polymer matrix.

Active Electronic Layer 420:

Active electronic layer 420 can include one or more layers. Active electronic layer 420 includes an active electronic material. Active electronic materials can include a single active electronic material, a combination of active electronic materials, or multiple layers of single or combined active electronic materials. Preferably, at least one active electronic material is organic.

For organic LEDs (OLEDs), the active electronic layer 316 contains at least one organic material that emits light. These organic light emitting materials generally fall into two categories. The first category of OLEDs, referred to as polymeric light emitting diodes, or PLEDs, utilize polymers as part of active electronic layer 420. The polymers may be organic or organometallic in nature. As used herein, the term organic also includes organometallic materials. Preferably, these polymers are solvated in an organic solvent, such as toluene or xylene, and spun (spin-coated) onto the device, although other deposition methods are possible. Devices utilizing polymeric active electronic materials in active electronic layer 316 are especially preferred. In addition to materials that emit light, active electronic layer 420 may include a light responsive material that changes its electrical properties in response to the absorption of light. Light responsive materials are often used in detectors and solar panels that convert light energy to electrical energy.

If the organic electronic device is an OLED or an organic laser, then the organic polymers are electroluminescent (“EL”) polymers that emit light. The light emitting organic polymers can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. Using inkjet printing, there may be a plurality of different emissive polymer substances. For instance, there may be red, green and blue emitting emissive polymers in the print head which are deposited depending upon the desired color to be emitted in a given pixel location which is defined by a pocket. The emitting polymer substances are deposited on the conducting polymer layer by the print head in the exact area defined by the pockets. The emissive polymer layer results from the drying of the substance deposited by the print head. More specifically, the organic polymers can be, for example: polyfluorenes; poly-p-phenylenevinylenes that emit white, red, blue, yellow, or green light and are 2-, or 2,5-substituted poly-p-pheneylenevinylenes; polyspiro polymers; LUMATION polymers that emit green, red, blue, or white light and are produced by Dow Chemical, Midland Mich.; or their families, copolymers, derivatives, or mixtures thereof.

If the organic electronic device is an organic solar cell or an organic light detector, then the organic polymers are light responsive material that changes its electrical properties in response to the absorption of light. The light responsive material converts light energy to electrical energy.

If the organic electronic device is an organic transistor, then the organic polymers can be, for example, polymeric and/or oligomeric semiconductors. The polymeric semiconductor can comprise, for example, polythiophene, poly(3-alkyl)thiophene, polythienylenevinylene, poly(para-phenylenevinylene), or polyfluorenes or their families, copolymers, derivatives, or mixtures thereof.

In addition to polymers, smaller organic molecules that emit by fluorescence or by phosphorescence can serve as a light emitting material residing in active electronic layer 420. Unlike polymeric materials that are applied as solutions or suspensions, small-molecule light emitting materials are preferably deposited through evaporative, sublimation, or organic vapor phase deposition methods. Small molecules, in accordance with the invention, may also be cross-linked similar to polymers. They may also be deposited using inkjet printing form solutions. These solutions may contain a cross linkable polymers that forms a matrix in which the small molecules are embedded. Cross-linked small molecule layers can be stacked one upon another, if desired. Combinations of PLED materials and smaller organic molecules can also serve as active electronic layer. For example, a PLED may be chemically derivatized with a small organic molecule or simply mixed with a small organic molecule to form active electronic layer 316.

In addition to active electronic materials that emit light, active electronic layer 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, compositions including C60, and compositions including derivatized C60 may be used. Active electronic layer 420 may also include semiconductors, such as silicon or gallium arsenide.

In accordance with the invention, the emissive polymer or active electronic layer 420 is fabricated by 1) depositing (through ink-jet) an emitting polymer substance (solution) over the cross-linked HTL film; and 2) if desired, cross-linking the active electronic layer 420 to render it insoluble. Multi-color OLED displays can be created in this manner as shown in FIG. 3.

One example of such emissive polymers are emissive polymers of the poly-spiro family (such as spirobifluorene-co-fluorenr polymers) which are soluble in toluene, ethanol and water. These emissive polymers (which can be synthesized/purchased in red, green and blue emitting forms) can be cross-linked with oxetane side-groups to render them insoluble. The emissive polymer solutions can also contain esters, di-aromatic bromides as well as a photo-acid to initiate cross-linking. The oxetane rings in this instance open up under application of UV radiation and cross-link with the emissive polymer. Such cross-linked films may also have to washed or otherwise neutralized by the addition of bases or nucleophiles. Often cross-linking by UV radiation can create side reactions with the emissive polymers such that radical cations are formed which adversely affect the electro-luminesence of the film. Post-baking and other steps may be needed after cross-linking if this is observed to be the case.

In some embodiments of the invention, a cross-linkable group can be grafted onto the base emissive polymer, and then the newly synthesized polymer solution is then deposited and cross-linked. In other embodiments of the invention, the active polymer species (the emissive polymer) can be added to a cross-linking polymer matrix.

Second Electrode (423)

In one embodiment, second electrode 423 functions as a cathode when an electric potential is applied across the first electrode 411 and second electrode 423. In this embodiment, when an electric potential is applied across the first electrode 411, which serves as the anode, and second electrode 423, which serves as the cathode, photons are released from active electronic layer 420 that pass through first electrode 411 and substrate 408.

While many materials, which can function as a cathode, are known to those of skill in the art, most preferably a composition that includes aluminum, indium, silver, gold, magnesium, calcium, and barium, or combinations thereof, or alloys thereof, is utilized. Aluminum, aluminum alloys, and combinations of magnesium and silver or their alloys are especially preferred.

Preferably, the thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred. Other layers (not shown) such as a barrier layer and getter layer may also be used to protect the electronic device. Such layers are well-known in the art and are not specifically discussed herein.

All of the organic or polymer layers and emissive polymer layers can be ink-jet printed by depositing a liquid solution in between the photo-resist banks which define a pocket. This liquid solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops.

Often other steps such as washing and neutralization of films, the addition of masks and photo-resists may precede the cathode deposition. However, these are not specifically enumerated as they do not relate specifically to the novel aspects of the invention. Other steps (not shown) like adding metal lines to connect the anode lines to power sources may also be included in the workflow. Also, for instance, after the OLED is fabricated it is often encapsulated to protect the layers from environmental damage or exposure. Such other processing steps are well-known in the art and are not a subject of the invention.

While the embodiments of the invention are illustrated in which it is primarily incorporated within an OLED display, almost any type of electronic device that uses dried film layers may be potential applications for these embodiments. In particular, present invention may also be utilized in a solar cell, a transistor, a phototransistor, a laser, a photo-detector, or an opto-coupler. It can also be used in biological applications such as bio-sensors or chemical applications such as applications in combinatorial synthesis etc. The OLED display described earlier can be used within displays in applications such as, for example, computer displays, information displays in vehicles, television monitors, telephones, printers, and illuminated signs.

1. An organic electronic device, comprising:
a deposition surface;
a first organic layer, said organic layer fabricated by selectively depositing a first organic solution over said deposition surface, further wherein said first organic solution is cross-linked to render said first organic layer insoluble; and
a second organic layer, said second organic layer fabricated by selectively depositing a second organic solution over said cross-linked first organic layer and enabling said second organic solution to dry without dissolving said first organic layer.

2. A device according to claim 1 further comprising: a third organic layer fabricated by cross-linking said second organic layer and selectively depositing a third organic solution upon said cross-linked second organic layer.

3. A device according to claim 1 wherein said cross-linking is performed by applying ultraviolet radiation to said device.

4. A device according to claim 1 wherein said first organic solution blends cross-linking groups for a base organic solution before said first organic solution is cross-linked.

5. A device according to claim 1 wherein said first organic solution includes an initiating agent to assist in the cross-linking process.

6. A device according to claim 1 wherein said cross-linking is achieved thermally.

7. A device according to claim 1 wherein said cross-linking is controlled to achieve a certain thickness for said cross-linked first organic layer.

8. A device according to claim 2 wherein said cross-linking is performed by applying ultraviolet radiation to said device.

9. A device according to claim 2 wherein said second organic solution blends cross-linking side-groups for a base organic solution before said second organic solution is cross-linked.

10. A device according to claim 2 wherein said second organic solution includes an initiating agent to assist in the cross-linking process.

11. A device according to claim 2 wherein said cross-linking is achieved thermally.

12. A device according to claim 1 wherein said cross-linking is controlled to achieve a certain thickness for said cross-linked second organic layer.

13. A device according to claim 1 wherein said first organic layer is a conducting polymer layer.

14. A device according to claim 1 wherein said organic electronic device is a OLED device.

15. A device according to claim 14 wherein said deposition surface is the lower electrode layer.

16. A device according to claim 15 wherein said second organic layer is an emissive layer, said emissive layer emitting light upon charge recombination.

17. A device according to claim 16 further comprising a cathode layer disposed over said emissive layer.

18. A device according to claim 13 wherein said conducting polymer layer is fabricated from a modified PEDOT:PSS solution.

19. A device according to claim 1 wherein said device behaves as an organic transistor.

20. A device according to claim 1 wherein said device behaves as an opto-electronic device.

21. A method of fabricating an organic electronic device, said device including a top exposed deposition surface, the method comprising:
depositing a first organic solution selectively on said exposed deposition surface, said deposited first organic solution capable of drying into a first organic layer;
cross-linking said first organic solution such that said first organic layer becomes insoluble; and
depositing a second organic solution selectively on said cross-linked first organic layer, said deposited second solution capable of drying into a second organic layer.

22. A method according to claim 21 wherein said second organic layer is formed by drying said deposited second organic solution.

23. A method according to claim 21 further comprising:
cross-linking said second organic solution such that said second organic layer becomes insoluble.

24. A method according to claim 23 further comprising:
depositing a third organic solution selectively into said pockets on said cross-linked second organic layer.

25. A method according to claim 21 wherein said first organic solution includes cross-linking side groups.

26. A method according to claim 21 wherein said first organic solution includes at least one of a cross-linking and initiating agent.

27. A method according to claim 21 wherein said organic electronic device is an organic light emitting diode (OLED) display.

28. A method according to claim 27 wherein said exposed deposition surface includes an anode.

29. A method according to claim 27 wherein said first organic layer is a conducting polymer layer.

30. A method according to claim 28 wherein said second organic layer is an emissive layer, said emissive layer emitting light upon charge recombination.

31. A method according to claim 29 wherein said first organic solution includes a modified PEDOT:PSS solution.

32. A method according to claim 21 wherein said device is an organic transistor.

33. A method according to claim 21 wherein said device is an organic opto-electronic device.

34. A method according to claim 21 wherein the steps of cross-linking previously deposited organic solutions and depositing another organic solution on the previously cross-linked organic layers is repeated for every organic layer that is to be fabricated.

35. A method according to claim 21 wherein said cross-linking is by application of ultraviolet radiation to said device.

36. A method according to claim 21 wherein said cross-linking is by application of thermal radiation to said device.

37. A method according to claim 23 further comprising:
masking said cross-linked second organic layer to block the application of radiation in those regions where said second organic solution had been deposited;
depositing a third organic solution selectively on said cross-linked first organic layer, said deposited third organic solution not deposited in any pockets containing said second organic solution; and
cross-linking said third organic solution such that the third organic layer formed therefrom becomes insoluble.

38. A method according to claim 37 further comprising:
masking said cross-linked second organic layer and said third organic layer to block the application of radiation in those regions where said second organic solution and said third organic solution have been deposited; and
depositing a fourth organic solution selectively into said pockets on said cross-linked first organic layer, said deposited fourth organic solution not deposited in any regions containing said second organic solution or said third organic solution, said deposited fourth organic solution capable of becoming a fourth organic layer.

39. A method according to claim 38 further comprising:
cross-linking said fourth organic solution to form a fourth organic layer therefrom.

40. A method according to claim 37 wherein said organic device is a multi-color organic light emitting diode (OLED) display.

41. A method according to claim 40 wherein said first organic layer is a conducting polymer layer.

42. A method according to claim 41 wherein said second organic layer is a first color emissive layer, said first color emissive layer emitting light of a first color upon charge recombination.

43. A method according to claim 42 wherein said third organic layer is a second color emissive layer, said second color emissive layer emitting light of a second color upon charge recombination.

44. A method according to claim 43 wherein said fourth organic layer is a third color emissive layer, said third color emissive layer emitting light of a third color upon charge recombination.

45. A method according to claim 44 wherein said first color is red, said second color is green and said third color is blue.
